(19) United States
(12) Patent Application Publication
(10) Pub. No.: US 2020/0328230 A1
(43) Pub. Date: Oct. 15, 2020

(54) DISPLAY PANEL AND DISPLAY DEVICE

(71) Applicants: Beijing BOE Optoelectronics Technology Co., Ltd., Beijing (CN); BOE TECHNOLOGY GROUP CO., LTD., Beijing (CN)

(72) Inventor: Pengqu Zhang, Beijing (CN)

(21) Appl. No.: 16/304,102

(22) PCT Filed: Mar. 22, 2018
(86) PCT No.: PCT/CN2018/080075

§ 371 Date: Nov. 21, 2018

(30) Foreign Application Priority Data
Apr. 19, 2017 (CN) 201710257808.1

(51) Int. Cl. H01L 27/12; G02F 1/1368; G02F 1/1362; G09G 3/36; G01R 31/317

(52) U.S. Cl. CPC H01L 27/124; G02F 1/1368; G02F 1/134363; G09G 3/3677; G01R 31/31712; G02F 1/136286

(57) ABSTRACT

The present disclosure relates to a display panel, and a display device including the same. The display panel includes a display area, including M scan lines and N data lines that are intersected, and a plurality of sub-pixels located in a sub-pixel area defined by respective scan lines and data lines, a first test area, comprising N first switching elements having a first end connected to a test signal end, and a control end connected to a first control signal, and N auxiliary switching elements having a first end connected to the nth data line, a second end connected to a second end of the nth first switching element, and the control end connected to a second control signal line; wherein, M and N are positive integers, and n≤N.

### CROSS REFERENCE

The present application is based upon International Application No. PCT/CN2018/080075, filed on Mar. 22, 2018, which is based upon and claims priority to Chinese Patent Application No. 201710257808.1, filed on Apr. 19, 2017, and the entire contents thereof are incorporated herein by reference.

### TECHNICAL FIELD

The present disclosure relates to the field of display technology, and in particular, to a display panel, and a display device including the same.

### BACKGROUND

In thin film transistor liquid crystal display products (TFT-LCD), with the continuous improvement of user experience requirements, the demand for high resolution (TFT-LCD) products also continues to increase.

Due to the increasing requirements for product resolution, the Fan-out area line density is increasing, and defect products may occur due to the limited wiring space. It is possible to reduce cost by intercepting defect products in an earlier stage of the manufacturing process.

It should be noted that the information disclosed in the background section above is only for enhancing the understanding of the background of the present disclosure, and thus may include information that does not constitute prior art known to those of ordinary skill in the art.

### SUMMARY

According to an aspect of the present disclosure, a display panel is provided, including a display area, including M scan lines and N data lines that are intersected, and a plurality of sub-pixels located in a sub-pixel area defined by respective scan lines and data lines, a first test area, comprising N first switching elements and the nth first switching element corresponding to a nth data line; a first end of each of the first switching elements is connected to a test signal end, and a control end of each of the first switching elements is connected to a first control signal, N auxiliary switching elements, wherein the nth auxiliary switching element corresponds to the nth first switching element, and a first end of the nth auxiliary switch is connected to the nth data line, a second end of the nth auxiliary switch is connected to a second end of the nth first switching element, and the control end of the nth auxiliary switch is connected to a second control signal line. M and N are positive integers, and n≤N.

In an exemplary arrangement of the present disclosure, each of the sub-pixels includes a second switching element; wherein the second switching element and the first switching element and the auxiliary switching element are all thin film transistors, and the thin film transistor includes a gate layer, a gate insulating layer, an active layer, and a source and drain metal layer which are stacked.

In an exemplary arrangement of the present disclosure, the gate layers, the gate insulating layers, the active layers, and the source and drain metal layers of the first switching element and the auxiliary switching element are disposed respectively in a same layer and have a same material with the gate layer, the gate insulating layer, the active layer, and the source and drain metal layer of the second switching element.

In an exemplary arrangement of the present disclosure, the first control signal line and the second control signal line are formed of a same signal line.

In an exemplary arrangement of the present disclosure, the first control signal line and the second control signal line are formed of different signal lines.

In an exemplary arrangement of the present disclosure, the display panel further includes a second test area, including an FPC test module disposed on a side of the display area opposite to the first test area.

In an exemplary arrangement of the present disclosure, the sub-pixel includes a pixel electrode and a common electrode; wherein the pixel electrode and the common electrode are disposed in different layers, and the pixel electrode has a comb-like structure.

In an exemplary arrangement of the present disclosure, the sub-pixel includes a pixel electrode and a common electrode; wherein the pixel electrode and the common electrode are disposed in a same layer and both have a comb-like structures.

According to another aspect of the present disclosure, a display device including the above display panel is provided.

In an exemplary arrangement of the present disclosure, the scan line is connected to a gate driving circuit, and the data line is connected to a source driving circuit; wherein the gate driving circuit is disposed on the display panel.

Other features and advantages of the present disclosure will be apparent from the following detailed description, or be acquired in part by the practice of the present disclosure.

It should be understood that the above general description and the following detailed description are merely exemplary and explanatory, and are not limiting of the present disclosure.

### BRIEF DESCRIPTION OF THE DRAWINGS

The drawings herein are incorporated into the specification and form part of the specification, showing arrangements consistent with the present disclosure, and are for explaining the principle of the present disclosure together with the specification. Obviously, the drawings in the following description are some arrangements of the present disclosure, and other drawings can be obtained based on these drawings for those skilled in the art without any creative labor.

FIG. 1 is a schematic structural view showing a display panel;

FIG. 2 is a schematic structural view showing a display panel in an exemplary arrangement of the present disclosure;

FIG. 3 is a schematic structural view showing another display panel in an exemplary arrangement of the present disclosure.

### DETAILED DESCRIPTION

Example arrangements will now be described more fully with reference to the drawings. However, the example arrangements can be embodied in various forms and should not be construed as being limited to the examples set forth herein; rather, these arrangements are provided so that the present disclosure will be more comprehensive and complete, and the conception of the example arrangements will be fully conveyed to those skilled in the art. The described features, structures, or characteristics may be combined in any suitable manner in one or more arrangements. However, one skilled in the art will appreciate that the technical solutions of the present disclosure can be practiced when one or more of the described specific details may be omitted or other methods, components, devices, blocks, etc. may be employed. In other cases, well-known technical solutions are not shown or described in detail to avoid obscuring aspects of the present disclosure.

In addition, the drawings are merely schematic representations of the present disclosure and are not necessarily to scale. The same reference numerals in the drawings denote the same or similar parts, thus the repeated description thereof will be omitted. Some of the block diagrams shown in the figures are functional entities and do not necessarily have to correspond to the physically or logically separate entities. These functional entities may be implemented in software, or implemented in one or more hardware modules or integrated circuits, or implemented in different network and/or processor devices and/or microcontroller devices.

The terms “a”, “an”, and “the” are used to mean the presence of one or more elements/components, etc.; the terms “including” and “having” are used to the inclusion of an open type, and mean that there may be additional elements/components/etc. in addition to the listed elements/components/etc.; the terms “first” and “second” etc. are used only as marks, not the limit of the number of objects.

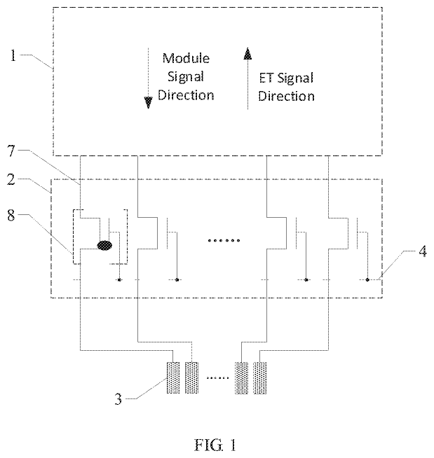

In the processes of the display panel, a photolithography process is indispensable. For example, referring to FIG. 1, since a growth type PT (bump) occurs on a mask during a photolithography process (SD Mask) in which a source and drain metal layer of a thin film transistor is formed, the source and drain metal remain may occur at fixed positions of the switching elements. Since the occurring position of the growth type PT is fixed, the occurring position of the source and drain metal remain is relatively fixed.

When the ET signal is applied to the product where the source and drain metal remain occurs, the DPO side (the side on the display panel opposite to the DP side) inputs the scan signal, and the data signal is input from the bottom to the top at the same time, although the source and drain metal remain occurs at the position of the switching element, the defect will not occur in the detection, so it is easy to miss the defect when detecting by the ET signal. During the normal screen display process, when signal is applied to the display module from the top to the bottom, the voltage at the switching element 8 where the source and drain metal remain occurs will be zero, and the signal of the display module signal is pulled down, thus causing line defects (X-Line). According to statistics, the incidence of line defects is above 4%.

In order to solve the above problem, the present arrangement firstly provides a display panel, which can be an ADS (Advanced Super Dimension Switch) display panel, an IPS (In-Plane Switching) display panel and the FFS (Fringe Field Switching) display panel, are used to prevent the occurrence of line defects when the source and drain metal remain occurs in the switching element. Of course, in other exemplary arrangements of the present disclosure, the display panel may be other types of display panels, which is not specifically limited in the exemplary arrangement.

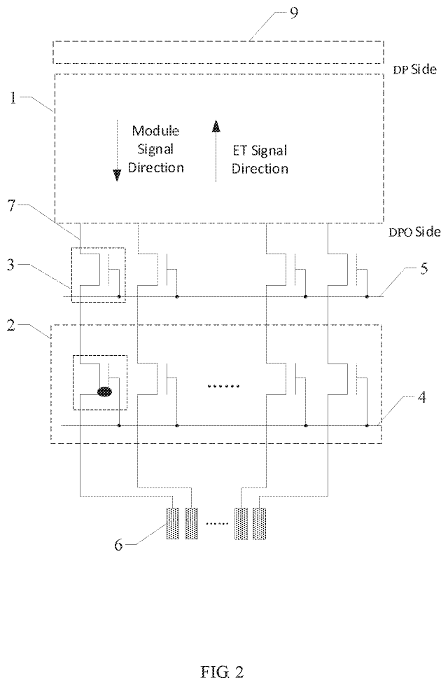

Referring to FIG. 2, the above display panel may include a display area 1, a first test area 2, and an auxiliary switching element 3 and the like. Wherein:

The display area 1 may include M scan lines and N data lines 7 that are intersected, and a plurality of sub-pixels located in a sub-pixel area defined by each of the scan lines and the data lines 7.

The first test area 2 may include N first switching elements and the nth first switching element corresponding to the nth data line 7; the first end of each of the first switching elements is connected to the test signal end 3, the control end is connected to the first control signal 4.

N auxiliary switching elements 3, wherein the nth auxiliary switching element 3 corresponds to the nth first switching element, and the first end of the nth auxiliary switch is connected to the nth data line 7, and the second end is connected to the second end of the nth first switching element, and the control end is connected to the second control signal line 5; wherein, M and N are positive integers, and

In the display panel provided by the exemplary arrangement, the auxiliary switching element 3 is disposed between the display area 1 and each of the first switching elements in the first test area 2, and each of the auxiliary switching elements 3 is connected to the second control signal line 5, even if the source and drain metal remain occurs in the first switching element, since the auxiliary switching element 3 can be normally disconnected, the module signal returned from the display area 1 can still be terminated at the auxiliary switching element 3 without causing line defect, thus reducing the rate of defective products and reducing the waste of module materials.

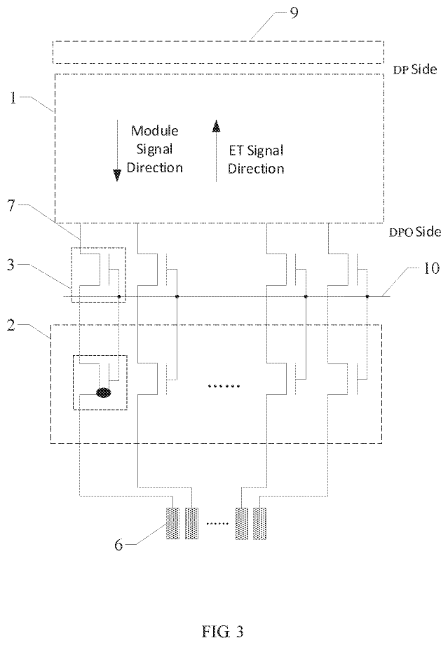

When detecting, referring to FIG. 2 or FIG. 3, an ET voltage is applied to the first control signal line 4 and the second control signal line 5, and the ET signal is applied from the bottom to the top; the data signal voltage is applied to the data line 7, and the data signal is from the bottom to the top. The test is normal at this time. When the module signal is returned, the module signal is from top to bottom, even if the source and drain metal remain occurs in the first switching element, since the auxiliary switching element 3 can be normally disconnected, the module signal returned from the display area 1 can still be terminated at the auxiliary switching element 3, thus not affecting the display of the screen. When there is no auxiliary switching element 3, the first switching element where the source and drain metal remains is turned on, the module signal is pulled down, and a line defect occurs.

Hereinafter, the display panel in the present exemplary arrangement will be described in more detail with reference to FIGS. 2 to 3.

In the present exemplary arrangement, the foregoing sub-pixels include a second switching element; wherein the second switching element and the first switching element and the auxiliary switching element 3 may all be thin film transistors, and the thin film transistor includes a gate layer, a gate insulating layer, an active layer, and a source and drain metal layer which are stacked. The gate layer, the gate insulating layer, the active layer, and the source and drain metal layer of the first switching element and the auxiliary switching element and the gate layer, the gate insulating layer, the active layer, and the source and drain metal layer of the second switching element are respectively disposed in the same layer and have the same material. The thin film transistor may be an N-type TFT or a P-type TFT, which is not particularly limited in the exemplary arrangement. In addition, it is easily understood by those skilled in the art that the order of the layers of the thin film transistor in the present exemplary arrangement is not particularly limited, for example, the thin film transistor may be a top gate type or a bottom gate type, which all fall within the protection scope of the present disclosure.

By forming the layer structures of the first switching element and the auxiliary switching element and the layer structure of the second switching element in the same layer, the same layer structure of each switching element can be formed in the same photolithography process, which can effectively simplify the process block, hereby reducing the cost.

In addition, in the exemplary arrangement, in the display panel described above, the first control signal line 4 and the second control signal line 5 may be different signal lines. Of course, referring to FIG. 3, in other exemplary arrangements of the present disclosure, the first control signal line 4 and the second control signal line 5 may also be the same signal line 10. When the first control signal line 4 and the second control signal line 5 are set to be the same control signal line 10, it is advantageous to reduce circuit wiring and facilitate the narrow bezel setting of the display device.

In addition, in the exemplary arrangement, the display panel may further include a second test area 9 including an FPC (Flexible Printed Circuit) test module. Referring to FIG. 2 or FIG. 3, the first test area 2 may be disposed on the DPO side of the display panel, and the second test area 9 is disposed on the DP side of the display panel.

When inspecting, the test signal end 6 is connected to the FPC test module, and the gradation potential VG is supplied from the FPC. A signal φR for selecting a data line for R is supplied to the R end. A signal φG for selecting a data line for G is supplied to the G end. A signal φB for selecting a data line for B is supplied to the B end. A control signal φC is supplied to the control end. An even data signal DE is supplied to the even test signal end. An odd data signal DO is supplied to the odd test signal end.

By setting the FPC test module, it is possible to receive signals from the data source for deeper and more accurate testing of the display area. And by disposing the FPC test module and the auxiliary switching element respectively on both sides of the display area, a reasonable layout of the display panel structure is realized, and the occupied space of the peripheral layout is reduced.

In the exemplary arrangement, the foregoing display panel sub-pixel further includes: the sub-pixel includes a pixel electrode and a common electrode; wherein the pixel electrode and the common electrode are disposed in different layers, and the pixel electrode is a comb-like structure. In other exemplary arrangements of the present disclosure, the sub-pixel includes a pixel electrode and a common electrode; wherein the pixel electrode and the common electrode may also be disposed in the same layer, and both are comb-like structures. By providing the pixel electrode of the comb-like structure, a multi-dimensional electric field can be formed by the electric field generated by the slit edge of the pixel electrode of the comb-like structure and the electric field generated between the pixel electrode and the common electrode, so that the pixel electrode of the comb-like structure in the liquid crystal cell and all the aligned liquid crystal molecules directly above the common electrode can be rotated, thus improving the liquid crystal working efficiency and increasing the light transmission efficiency.

It can be seen from the above technical solution that the display panel provided by the present disclosure has the advantages and positive effects that: by providing an auxiliary switching element between the display area and each of the first switching elements, and each of the auxiliary switching elements is connected to the second control signal line, even if the source and drain metal remain occurs in the first switching element, since the auxiliary switching element can be normally disconnected, the module signal returned from the display area can be terminated at the auxiliary switching element without causing a line defect.

According to some arrangements of the present disclosure, there is also provided a display device comprising the above display panel. The scan line on the display panel is connected to the gate driving circuit, and the data line on the display panel is connected to the source driving circuit. And, the gate driving circuit can be disposed on the display panel. The display device is provided with two sets of switching elements, and even if the source and drain metal remain occurs in the first switching element in the first test area, the module signal of the display area downward can still be terminated at the auxiliary switching element corresponding to the first switching element, so that the module signal is not pulled down and ensure that the display device is normally displayed.

Other arrangements of the disclosure will be readily apparent to those skilled in the art upon consideration of the specification and practice of the disclosure herein disclosed herein. The present application is intended to cover any variations, uses, or adaptations of the present disclosure, which are in accordance with the general principles of the present disclosure and include common general knowledge or conventional technical means in the art that are not disclosed in the present disclosure. The specification and examples are to be considered as illustrative only, the true scope and spirit of the disclosure is pointed out by the following claims.

1. A display panel, comprising:
a display area, including M scan lines and N data lines that are intersected, and a plurality of sub-pixels located in a sub-pixel area defined by respective scan lines and data lines;
a first test area, comprising N first switching elements, and an nth first switching element of the first switching elements corresponds to an nth data line; a first end of each of the first switching elements is connected to a test signal end, and a control end of each of the first switching elements is connected to a first control signal; and
N auxiliary switching elements, wherein an nth auxiliary switching element of the auxiliary switching elements corresponds to the nth first switching element, and a first end of the nth auxiliary switch is connected to the nth data line, a second end of the nth auxiliary switch is connected to a second end of the nth first switching element, and the control end of the nth auxiliary switch is connected to a second control signal line;
wherein, M and N are positive integers, and n≤N.

2. The display panel according to claim 1, wherein each of the sub-pixels includes a second switching element; and wherein the second switching element and the first switching element and the auxiliary switching element are all thin film transistors, and the thin film transistor includes a gate layer, a gate insulating layer, an active layer, and a source and drain metal layer which are stacked.

3. The display panel according to claim 2, wherein the gate layers, the gate insulating layers, the active layers, and the source and drain metal layers of the first switching element and the auxiliary switching element are disposed respectively in a same layer and have a same material with the gate layer, the gate insulating layer, the active layer, and the source and drain metal layer of the second switching element.

4. The display panel according to claim 1, wherein the first control signal line and the second control signal line are formed of a same signal line.

5. The display panel according to claim 1, wherein the first control signal line and the second control signal line are formed of different signal lines.

6. The display panel according to claim 1, wherein the display panel further comprises:
a second test area, including an FPC test module disposed on a side of the display area opposite to the first test area.

7. The display panel according to claim 1, wherein the sub-pixel comprises a pixel electrode and a common electrode; wherein the pixel electrode and the common electrode are disposed in different layers, and the pixel electrode has a comb-like structure.

8. The display panel according to claim 1, wherein the sub-pixel comprises a pixel electrode and a common electrode; wherein the pixel electrode and the common electrode are disposed in a same layer and both have a comb-like structures.

9. A display device, wherein the display device comprises the display panel comprising:
a display area, including M scan lines and N data lines that are intersected, and a plurality of sub-pixels located in a sub-pixel area defined by respective scan lines and data lines;
a first test area, comprising N first switching elements, and an nth first switching element of the first switching elements corresponds to an nth data line; a first end of each of the first switching elements is connected to a test signal end, and a control end of each of the first switching elements is connected to a first control signal; and
N auxiliary switching elements, wherein an nth auxiliary switching element of the auxiliary switching elements corresponds to the nth first switching element, and a first end of the nth auxiliary switch is connected to the nth data line, a second end of the nth auxiliary switch is connected to a second end of the nth first switching element, and the control end of the nth auxiliary switch is connected to a second control signal line;
wherein, M and N are positive integers, and n≤N.

10. The display device according to claim 9, wherein the scan line is connected to a gate driving circuit, and the data line is connected to a source driving circuit; and wherein the gate driving circuit is disposed on the display panel.

11. The display device according to claim 9, wherein each of the sub-pixels includes a second switching element; and wherein the second switching element and the first switching element and the auxiliary switching element are all thin film transistors, and the thin film transistor includes a gate layer, a gate insulating layer, an active layer, and a source and drain metal layer which are stacked.

12. The display device according to claim 11, wherein the gate layers, the gate insulating layers, the active layers, and the source and drain metal layers of the first switching element and the auxiliary switching element are disposed respectively in a same layer and have a same material with the gate layer, the gate insulating layer, the active layer, and the source and drain metal layer of the second switching element.

13. The display device according to claim 9, wherein the first control signal line and the second control signal line are formed of a same signal line.

14. The display device according to claim 9, wherein the first control signal line and the second control signal line are formed of different signal lines.

15. The display device according to claim 9, wherein the display panel further comprises:
a second test area, including an FPC test module disposed on a side of the display area opposite to the first test area.

16. The display device according to claim 9, wherein the sub-pixel comprises a pixel electrode and a common electrode; wherein the pixel electrode and the common electrode are disposed in different layers, and the pixel electrode has a comb-like structure.

17. The display device according to claim 9, wherein the sub-pixel comprises a pixel electrode and a common electrode; wherein the pixel electrode and the common electrode are disposed in a same layer and both have a comb-like structures.
